(19) United States
(12) Patent Application Publication
(10) Pub. No.: US 2026/0171167 A1
(43) Pub. Date: Jun. 18, 2026

(54) MEMORY DEVICE AND STORAGE DEVICE INCLUDING THE SAME

(71) Applicant: SAMSUNG ELECTRONICS CO., LTD., Suwon-si (KR)

(72) Inventors: Sang-Won SHIM, Suwon-si (KR); Hanseul KIM, Suwon-si (KR)

(73) Assignee: SAMSUNG ELECTRONICS CO., LTD., Suwon-si (KR)

(21) Appl. No.: 19/329,851

(22) Filed: Sep. 16, 2025

(30) Foreign Application Priority Data
Dec. 18, 2024 (KR) 10-2024-0189615

(51) Int. Cl. G11C 16/30; G11C 5/14

(52) U.S. Cl. CPC G11C 16/30; G11C 5/145; G11C 5/147

(57) ABSTRACT

A memory device includes a load circuit, one or more reference voltage generators, a voltage regulator, and a clamp circuit. The one or more reference voltage generators are configured to generate an internal power reference voltage. The voltage regulator is configured to generate an internal voltage based on the internal power reference voltage and supply the generated internal voltage to the load circuit. The clamp circuit is configured to control a level of the internal voltage.

### CROSS-REFERENCE TO RELATED APPLICATION

This application claims priority to Korean Patent Application No. 10-2024-0189615, filed in the Korean Intellectual Property Office on Dec. 18, 2024, the entire contents of which are hereby incorporated by reference.

### BACKGROUND

### Field

The present disclosure relates to a memory device and a storage device including the same.

### Description of Related Art

A semiconductor memory may be classified into a volatile memory device such as a static RAM (SRAM), a dynamic RAM (DRAM), a synchronous DRAM (SDRAM), etc. in which stored data is destroyed upon power cut off, and a non-volatile memory device such as a read only memory (ROM), a programmable ROM (PROM), an electrically erasable and programmable ROM (EPROM), a flash memory device, a phase-change RAM (PRAM), a magnetic RAM (MRAM), a respective RAM (RRAM), a ferroelectric RAM (FRA), etc. in which stored data is maintained even when power is cut off.

### SUMMARY

In order to solve one or more problems (e.g., the problems described above and/or other problems not explicitly described herein), the present disclosure provides a memory device for enhancing the reliability of a circuit in the memory device by preventing an abnormal increase in an internal voltage of the memory device, and a storage device including the same.

The object to be achieved by the present disclosure is not limited to the above, and other objects not explicitly described herein may be clearly understood by those skilled in the art from the description of the present disclosure.

A memory device may be provided, including a load circuit, reference voltage generators configured to generate an internal power reference voltage, a voltage regulator configured to generate an internal voltage based on the internal power reference voltage and supply the generated internal voltage to the load circuit, and a clamp circuit configured to control a level of the internal voltage, in which the voltage regulator may be further configured to generate a standby voltage based on the internal power reference voltage in a standby mode of the load circuit and supply the generated standby voltage to the load circuit as the internal voltage, and the clamp circuit may be further configured to, in response to the standby voltage increasing to a first level exceeding a threshold level in the standby mode of the load circuit, lower the standby voltage to a second level equal to or lower than the threshold level.

A memory device may be provided, including a load circuit, reference voltage generators configured to generate an internal power reference voltage, a voltage regulator configured to generate an internal voltage based on the internal power reference voltage and supply the generated internal voltage to the load circuit, and a clamp circuit configured to control a level of the internal voltage, in which the voltage regulator may be further configured to generate a standby voltage based on the internal power reference voltage in a standby mode of the load circuit and supply the generated standby voltage to the load circuit as the internal voltage, and the clamp circuit may be further configured to, in response to the standby voltage increasing to a first level exceeding a threshold level in the standby mode of the load circuit, lower the standby voltage to a second level equal to or lower than the threshold level, the clamp circuit may include a PMOS transistor, a comparator configured to compare the standby voltage and the threshold level, output a high level to a gate electrode of the PMOS transistor in response to the standby voltage exceeding the threshold level, and output a low level to the gate electrode of the PMOS transistor in response to the standby voltage being equal to or lower than the threshold level, one or more logic gates and connected to a drain node of the PMOS transistor and generating a discharge signal in response to the PMOS transistor being turned off with the high level applied to the gate electrode of the PMOS transistor, a plurality of first NMOS transistors with source nodes thereof connected to the internal voltage and configured to be turned on in response to the discharge signal being applied to gate electrodes thereof, and a plurality of second NMOS transistors with source nodes thereof connected to drain nodes of the plurality of first NMOS transistors and with drain nodes thereof connected to a ground node, in which at least some of the second NMOS transistors may be turned on in the standby mode of the load circuit, and in response to the plurality of first NMOS transistors being turned on, the standby voltage may be discharged through the ground node connected to at least some of the turned-on second NMOS transistors.

A storage device may be provided, including a memory device including a load circuit, reference voltage generators configured to generate an internal power reference voltage, a voltage regulator configured to generate an internal voltage based on the internal power reference voltage and supply the generated internal voltage to the load circuit, and a clamp circuit configured to control a level of the internal voltage, and a storage controller connected to the memory device, in which the voltage regulator may be further configured to generate a standby voltage based on the internal power reference voltage in a standby mode of the load circuit and supply the generated standby voltage to the load circuit as the internal voltage, and the clamp circuit may be further configured to, in response to the standby voltage increasing to a first level exceeding a threshold level in the standby mode of the load circuit, lower the standby voltage to a second level equal to or lower than the threshold level.

According to various aspects of the present disclosure, if the internal voltage abnormally increases, the internal voltage can be discharged using the clamp circuit, so that the internal voltage can be stably supplied to the load circuit.

According to various aspects of the present disclosure, reliability of the memory device or the load circuit in the memory device can be improved.

The effects that can be obtained through the present disclosure are not limited to those described above. Technical effects not mentioned herein will be clearly understood by those skilled in the art from the description of the present disclosure described below.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a diagram illustrating a storage system;

FIG. 2 is a block diagram illustrating a memory device;

FIG. 3 is a perspective view illustrating a memory block;

FIG. 4 is a circuit diagram illustrating a memory block;

FIG. 5 is a block diagram illustrating the voltage generating circuit of FIG. 2 in detail;

FIG. 6 is a diagram illustrating the internal power reference voltage generator and the voltage regulator of FIG. 5 in more detail;

FIG. 7 is a diagram illustrating the active driver of FIG. 6 in detail;

FIG. 8 is a diagram illustrating changes in an internal voltage according to the voltage generating circuit of FIG. 6;

FIG. 9 is a diagram illustrating an example of a voltage generating circuit including a clamp circuit;

FIG. 10 is a block diagram illustrating the clamp circuit of FIG. 9 in more detail;

FIG. 11 is a circuit diagram illustrating the clamp circuit of FIG. 9 in detail;

FIG. 12 is a diagram illustrating changes in the internal voltage according to the clamp circuit of FIG. 11; and

FIG. 13 is a block diagram illustrating a voltage generating circuit.

### DETAILED DESCRIPTION

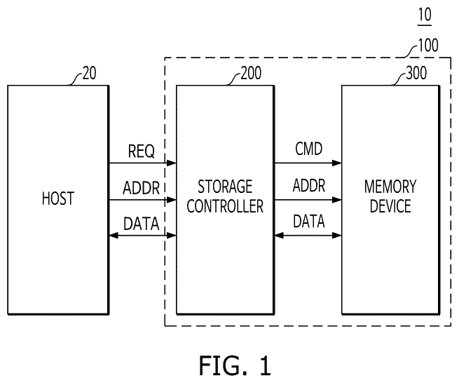

Various aspects of the present disclosure will be described with reference to FIGS. 1 to 13. Throughout the description, the same reference numerals may refer to the same components.

FIG. 1 is a diagram illustrating a storage system 10. Referring to FIG. 1, the storage system 10 may include a host device 20 and a storage device 100.

The storage system 10 may be applied to one of various computing systems such as an ultra-mobile PC (UMPC), a workstation, a netbook, personal digital assistants (PDA), a portable computer, a web tablet, a wireless phone, a mobile phone, a smart phone, an e-book, a portable multimedia player (PMP), a portable game machine, a navigation device, a black box, and a digital camera.

The host device 20, a storage controller 200, and a memory device 300 may each be provided as one chip, one package, or one module, etc. However, aspects are not limited thereto, and for example, the storage controller 200 along with the memory device 300 may be provided as the storage device 100.

The host device 20 may transmit a data operation request REQ and an address ADDR to the storage controller 200. In addition, the host device 20 and the storage device 100 may transmit and receive data DATA and/or signals to and from each other. For example, the host device 20 may exchange the data DATA and/or the signals with the storage controller 200 based on at least one of various interface protocols such as Universal Serial Bus (USB) protocol, Multi Media Card (MMC) protocol, Peripheral Component Interconnection (PCI) protocol, PCI-Express (PCI-E) protocol, Advanced Technology Attachment (ATA) protocol, Serial-ATA protocol, Parallel-ATA protocol, Small Computer Small Interface (SCSI) protocol, Enhanced Small Disk Interface (ESDI) protocol, Integrated Drive Electronics (IDE) protocol, Mobile Industry Processor Interface (MIPI) protocol, and Universal Flash Storage (UFS) protocol.

The storage controller 200 may control the memory device 300. For example, in response to the data operation request REQ received from the host device 20, the storage controller 200 may control the memory device 300 to read the data DATA stored in the memory device 300 or to write the data DATA to the memory device 300. For example, the storage controller 200 may provide an address ADDR, a command CMD, a control signal, etc. to the memory device 300 to control write, read, and erase operations of the memory device 300. In addition, the data DATA for operations may be transmitted and received between the storage controller 200 and the memory device 300.

The memory device 300 may include at least one memory cell array. The memory cell array may include a plurality of memory cells disposed in regions where a plurality of word lines and a plurality of bit lines intersect, and the plurality of memory cells may be volatile memory cells or non-volatile memory cells. Each of the memory cells may be a multi-level cell storing data with 2 bits or more. For example, each of the memory cells may be a 2-bit multi-level cell that stores 2 bits data, a triple-level cell (TLC) that stores 3 bits of data, or a quadruple-level cell (QLC) that stores 4 bits of data, or a multi-level cell that stores more than 4 bits of data. Aspects are not limited to the above, and for example, some of the memory cells may be single-level cells (SLCs) storing 1 bit of data, and the other memory cells may be multi-level cells.

The memory device 300 may include at least one of the volatile or non-volatile memories, such as a NAND flash memory (NAND flash memory), a vertical NAND (VNAND), a static RAM (SRAM), a dynamic RAM (DRAM), a synchronous DRAM (SDRAM), a read only memory (ROM), a programmable ROM (PROM), an electrically programmable ROM (EPROM), an electrically erasable and programmable ROM (EEPROM), a magnetic RAM (MRAM), a spin-transfer torque RAM (MRAM), a conductive bridging RAM (CBRAM), a ferroelectric RAM (FeRAM), a phase RAM (PRAM), and a resistive RAM.

In response to the signals received from the storage controller 200, the memory device 300 may perform operations such as the write operation, the read operation, and the erase operation of the data DATA.

The memory device 300 may include various types of load circuits that operate using the internal voltage of the memory device 300. For example, the load circuit of the memory device 300 may include a memory cell array, an address decoder, a control logic circuit, a page buffer circuit, an input/output circuit, etc.

The storage controller 200 may determine a mode of the load circuit of the memory device 300. For example, the load circuit may operate in standby or active mode, and the storage controller 200 may determine the mode of the load circuit as the standby or active mode, and control the memory device 300 such that the load circuit operates in the standby or active mode. In response to determining the mode of the load circuit to be the standby mode, the storage controller 200 may control the memory device 300 to generate a standby voltage to be supplied to the load circuit. In response to determining the mode of the load circuit to be the active mode, the storage controller 200 may control the memory device 300 to generate an active voltage to be supplied to the load circuit.

In response to an abnormal increase in the level of the internal voltage applied to the load circuit of the memory device 300, the storage controller 200 may control a clamp circuit so that the clamp circuit associated with the load circuit controls the level of the internal voltage. For example, in response to determining the mode of the load circuit to be the standby mode, the storage controller 200 may switch the clamp circuit to a state in which it is allowed to vary the level of the internal voltage applied to the load circuit. Alternatively, in response to determining the mode of the load circuit to be the active mode, the storage controller 200 may switch the clamp circuit to a state in which it is not allowed to vary the level of the internal voltage applied to the load circuit.

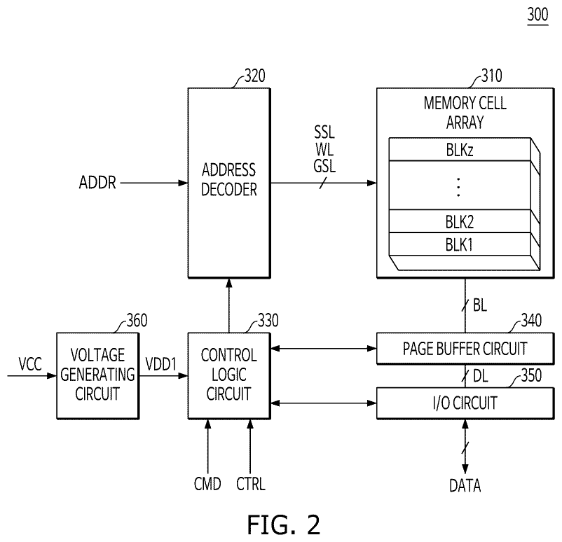

FIG. 2 is a block diagram illustrating the memory device. Referring to FIG. 2, the memory device 300 may include a memory cell array 310, an address decoder 320, a control logic circuit 330, a page buffer circuit 340, an input/output circuit 350, and a voltage generating circuit 360.

The memory cell array 310 may include a plurality of memory blocks BLK1 to BLKz (where, z is a natural number greater than or equal to 2). Each of the plurality of memory blocks may include a plurality of cell strings, and each of the plurality of cell strings may include a plurality of cell transistors. The plurality of cell transistors may be connected in series between bit lines BL and a common source line CSL, and may be connected to string select lines SSL, word lines WL, and ground select lines GSL. The plurality of memory blocks may have a three-dimensional structure including the memory cells (or word lines) stacked in a direction perpendicular to a substrate, although the aspects are not limited thereto.

The address decoder 320 may be connected to the memory cell array 310 through the string select lines SSL, the word lines WL, and the ground select lines GSL. The address decoder 320 may receive the address ADDR from an external device such as the storage controller (e.g., 200 of FIG. 1) and decode the received address ADDR. The address decoder 320 may control the string select lines SSL, the word lines WL, and the ground select lines GSL based on the decoding result.

The control logic circuit 330 may control various components of the memory device 300 in response to the signals (e.g., a command CMD, a control signal CTRL, etc.) received from the storage controller (e.g., 200 of FIG. 1).

The page buffer circuit 340 may be connected to the memory cell array 310 through the bit lines BL. The page buffer circuit 340 may read the data stored in the memory cell array 310 by sensing a voltage change of the bit lines BL. The page buffer circuit 340 may store data in the memory cell array 310 by controlling the voltage of the bit lines BL.

The input/output circuit 350 may receive the data DATA from an external device (e.g., a controller) and transmit the received data to the page buffer circuit 340 through the data lines DL. The input/output circuit 350 may receive the data DATA from the page buffer circuit 340 through the data lines DL and transmit the received data DATA to the external device.

The voltage generating circuit 360 may generate various voltages required to operate the memory device 300. For example, the voltage generating circuit 360 may generate various voltages such as a plurality of program voltages, a plurality of pass voltages, a plurality of verification voltages, a plurality of read voltages, a plurality of unselect read voltages, a plurality of erase voltages, and a plurality of erase verification voltages. For simplicity of the drawings, FIG. 2 illustrates that the voltage generated from the voltage generating circuit 360 is provided to the control logic circuit 330, but aspects are not limited thereto, and various voltages generated from the voltage generating circuit 360 may be provided to various components of the memory device 300.

The voltage generating circuit 360 may generate various internal voltages required in the memory device 300 and provide the generated internal voltages to various components in the memory device 300. The load current used in the memory device 300 may change according to the operation state of the memory device 300, and in this case, the level of the internal voltage may change.

For example, the voltage generating circuit 360 may generate a driving voltage required to drive a transistor in the memory device 300 and provide the driving voltage to the transistor in the memory device 300. In addition, for example, the voltage generating circuit 360 may generate an internal voltage required by the page buffer circuit 340 and provide the generated internal voltage to the page buffer circuit 340. In addition, the voltage generating circuit 360 may include one or more of various types of power circuits to generate the internal voltage as described above. The power circuits may include one or more of various types of AC-DC converters, DC-DC converters, and AC-AC converters.

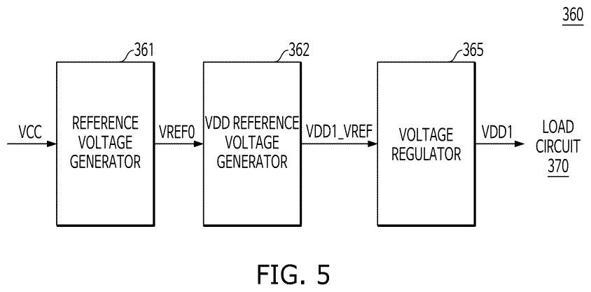

In general, it is preferable that the specific internal voltage generated by the voltage generating circuit 360 has a specific level. In other words, the internal voltage may preferably have a stabilized value. However, if the memory device 300 operates at high speeds, the internal voltage may have a different level than a required specific level due to load effect, leakage current, etc., and the internal voltage may show unstabilized value. As a result, noise may be generated in the internal voltage generated by the voltage generating circuit 360. To address this, the voltage generating circuit 360 may include a voltage regulator for maintaining the internal voltage at a constant level. The configuration and operation of the voltage generating circuit 360 or the voltage regulator will be described in more detail with reference to FIGS. 5 to 13.

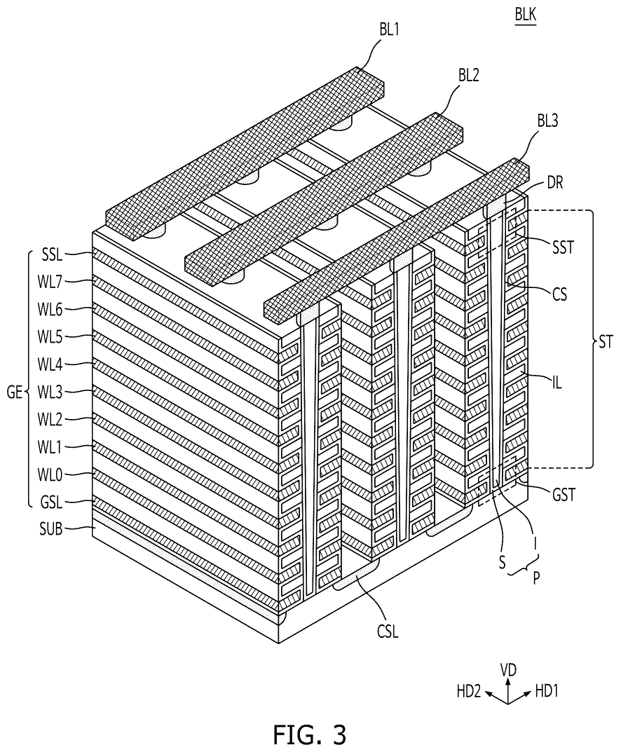

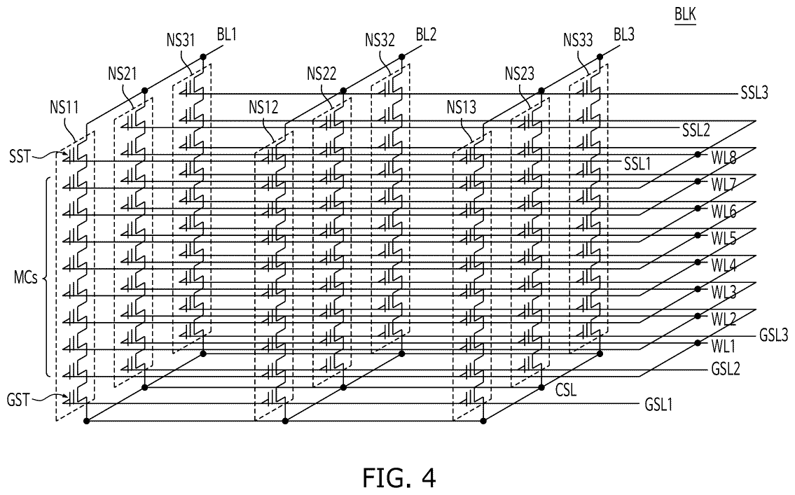

FIG. 3 is a perspective view of a memory block BLK, and FIG. 4 is a circuit diagram of the memory block BLK. The memory block BLK illustrated and described with reference to FIGS. 3 and 4 may be any one of the plurality of memory blocks BLK1 to BLKz in FIG. 2, and the following description may be applicable equally to each of the plurality of memory blocks BLK1 to BLKz.

Referring to FIG. 3, the memory block BLK may include a stack ST which extends on a substrate SUB in a vertical direction VD. For example, the memory block BLK may include a single stack ST between the substrate SUB and bit lines BL1 to BL3. The common source line CSL may be disposed on the substrate SUB, and, on a region of the substrate SUB between two adjacent common source lines CSL, there are insulating films IL extending in a second horizontal direction HD2 and sequentially provided in the vertical direction VD, in which the insulating films IL may be spaced apart by a specific distance in the vertical direction VD. Pillars P formed through the insulating films IL in the vertical direction VD may be provided on the region of the substrate SUB between two adjacent common source lines CSL. The pillars may be referred to as channel holes. The pillars P may be formed in a cup shape (or a cylindrical shape with a closed bottom) extending in the vertical direction VD. A surface layer S of each of the pillars P may include a silicon material of a first type and may serve as a channel region. On the other hand, an inner layer I of each of the pillars P may include an insulating material such as silicon oxide, or an air gap.

In the region between two adjacent common source lines CSL, a charge storage layer CS may be provided along exposed surfaces of the insulating films IL, the pillars P, and the substrate SUB. The charge storage layer CS may include a gate insulating layer, a charge trap layer, and a blocking insulating layer. For example, the charge storage layer CS may have an oxide-nitride-oxide (ONO) structure. In addition, gate electrodes GE such as select lines GSL and SSL and word lines WL1 to WL8 may be provided on an exposed surface of the charge storage layer CS in the region between the two adjacent common source lines CSL. Drains DR may be provided on each of the plurality of pillars P. The bit lines BL1 to BL3 may be provided on the drains DR, extending in a first horizontal direction HD1 and spaced apart from each other by a specific distance in the second horizontal direction HD2.

Referring to FIG. 4, the memory block BLK may include NAND strings NS11 to NS33, and each (e.g., NS11) of the NAND strings NS11 to NS33 may include a string select transistor SST, a plurality of memory cells MCs, and a ground select transistor GST connected in series. The transistors SST and GST and the memory cells MCs included in each NAND string may form a vertically stacked structure on the substrate.

The bit lines BL1 to BL3 may extend in the first direction, and the word lines WL1 to WL8 may extend in a second direction intersecting with the first direction. The NAND strings NS11, NS21, and NS31 may be positioned between the first bit line BL1 and the common source line CSL, the NAND strings NS12, NS22, and NS32 may be positioned between the second bit line BL2 and the common source line CSL, and the NAND strings NS13, NS23, and NS33 may be positioned between the third bit line BL3 and the common source line CSL.

The string select transistor SST may be connected to corresponding string select lines SSL1 to SSL3. The memory cells MCs may be connected to the corresponding word lines WL1 to WL8, respectively. The ground select transistor GST may be connected to corresponding ground select lines GSL1 to GSL3. The string select transistor SST may be connected to the corresponding bit line, and the ground select transistor GST may be connected to the common source line CSL. The number of NAND strings, the number of word lines, the number of bit lines, the number of ground select lines, and/or the number of string select lines may be variously changed according to aspects.

FIG. 5 is a block diagram illustrating the voltage generating circuit 360 of FIG. 2 in detail. For convenience of description, aspects of the voltage generating circuit 360 generating an internal voltage VDD1 will be mainly described. However, aspects are not limited thereto, and the voltage generating circuit 360 may generate various operating voltages described above, and may further include a plurality of voltage regulators configured to control various operating voltages, respectively. Each of the plurality of voltage regulators may have a similar configuration or operate similarly to a voltage regulator to be described below.

Referring to FIG. 5, the voltage generating circuit 360 may include a reference voltage generator 361, an internal power reference voltage generator 362, and a voltage regulator 365.

The reference voltage generator 361 may be configured to generate a reference voltage VREF0. For example, the reference voltage generator 361 may be a band gap reference (BGR) circuit configured to generate the reference voltage VREF0. The reference voltage generator 361 may generate the reference voltage VREF0 using an external voltage VCC.

The internal power reference voltage generator 362 may generate an internal power reference voltage VDD1_VREF using the reference voltage VREF0.

The reference voltage generator 361 and the internal power reference voltage generator 362 are illustrated as separate configurations, but they may be configured or referred to as a single reference voltage generator configured to generate the internal power reference voltage VDD1_VREF.

The voltage regulator 365 may generate the internal voltage VDD1 based on the internal power reference voltage VDD1_VREF and supply the generated internal voltage VDD1 to a load circuit 370. The internal voltage VDD1 may be provided to the load circuit 370 included in the memory device 300. The load circuit 370 may include at least one of various components of the memory device 300 that use the internal voltage VDD1 (e.g., the memory cell array 310, the address decoder 320, the control logic circuit 330, the page buffer circuit 340, the input/output circuit 350, etc. of FIG. 2).

The voltage regulator 365 may be configured to offset a change in the internal voltage VDD1 caused by a change in the load current used in the load circuit 370 and provide a stable internal voltage VDD1.

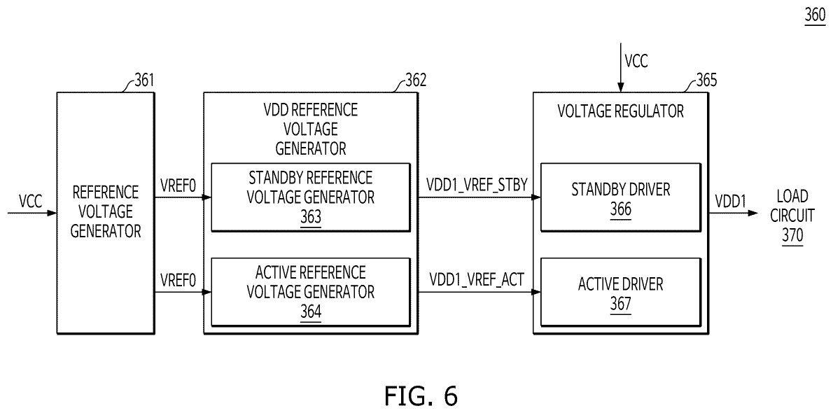

FIG. 6 is a diagram illustrating the internal power reference voltage generator 362 and the voltage regulator 365 of FIG. 5 in more detail.

The internal power reference voltage generator 362 may include a standby reference voltage generator 363 and an active reference voltage generator 364.

The standby reference voltage generator 363 may generate a standby reference voltage VDD1_VREF_STBY using a first reference voltage VREF0 in the standby mode of the load circuit 370. The active reference voltage generator 364 may generate an active reference voltage VDD1_VREF_ACT using the first reference voltage VREF0 in the active mode of the load circuit 370. The internal power reference voltage VDD1_VREF of FIG. 5 may include the standby reference voltage VDD1_VREF_STBY and the active reference voltage VDD1_VREF_ACT.

The voltage regulator 365 may include a standby driver 366 and an active driver 367. Each of the standby driver 366 and the active driver 367 may generate the internal voltage VDD1 using the external voltage VCC.

The standby driver 366 may generate the standby voltage based on the standby reference voltage VDD1_VREF_STBY in the standby mode of the load circuit 370 and supply the generated standby voltage to the load circuit 370 as the internal voltage VDD1. For example, in response to determining the mode of the load circuit 370 to the standby mode, the storage controller (e.g., 200 in FIG. 1) may control the memory device to generate the standby voltage in the voltage regulator 365.

The active driver 367 may generate the active voltage based on the active reference voltage VDD1_VREF_ACT in the active mode of the load circuit 370 and supply the generated active voltage to the load circuit 370 as the internal voltage VDD1. For example, in response to determining the mode of the load circuit 370 to be the active mode, the storage controller may control the memory device to generate the active voltage in the voltage regulator 365.

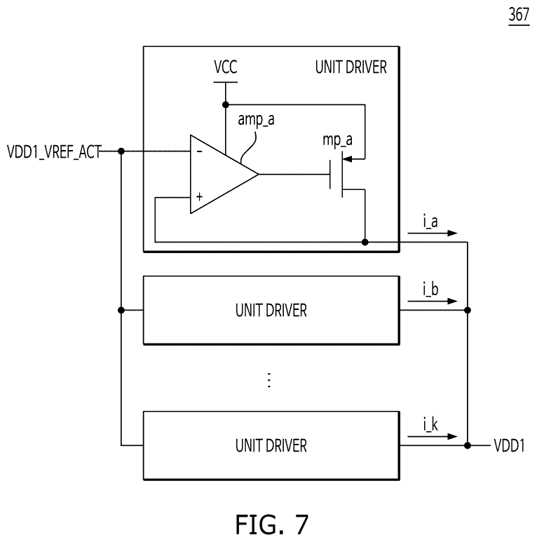

FIG. 7 is a diagram illustrating the active driver 367 of FIG. 6 in detail.

The active driver 367 may be activated in the active mode of the load circuit (e.g., 370 of FIG. 6) and may be deactivated in the standby mode. The active driver 367 may generate the internal voltage VDD1 (e.g., the active voltage) based on the active reference voltage VDD1_VREF_ACT.

The active driver 367 may include a plurality of unit drivers. The plurality of unit drivers may be connected to each other in parallel.

The active driver 367 may be a low dropout (LDO) circuit. For example, each of the plurality of unit drivers may be a low dropout circuit.

Each of the plurality of unit drivers may include an amplifier amp_a and a pass transistor mp_a. The internal voltage VDD1 (e.g., the active voltage) may be generated using the amplifiers amp_a and the pass transistors mp_a of the plurality of unit drivers.

An inverting input (−) of the amplifier amp_a may be connected to the active reference voltage VDD1_VREF_ACT, and a non-inverting input (+) of the amplifier amp_a may be connected to the internal voltage VDD1. The pass transistor mp_a may be a PMOS transistor that is connected between the external voltage VCC and the internal voltage VDD1 and configured to operate in response to the output of the amplifier amp_a. In this case, if the load current increases and the internal voltage VDD1 drops below the target level, the output level of the amplifier amp_a decreases, which causes the current (i.e., i_a) flowing through the pass transistor mp_a to increase, thereby stabilizing the internal voltage VDD1 (e.g., the active voltage). Likewise, the other unit drivers may adjust the levels of a plurality of currents i_b through i_k to respond to changes in the load current.

Each of the plurality of unit drivers included in the active driver 367 may have the same or similar physical characteristics. For example, the amplifiers and pass transistors included in each of the plurality of unit drivers may have the same size or the same physical characteristics.

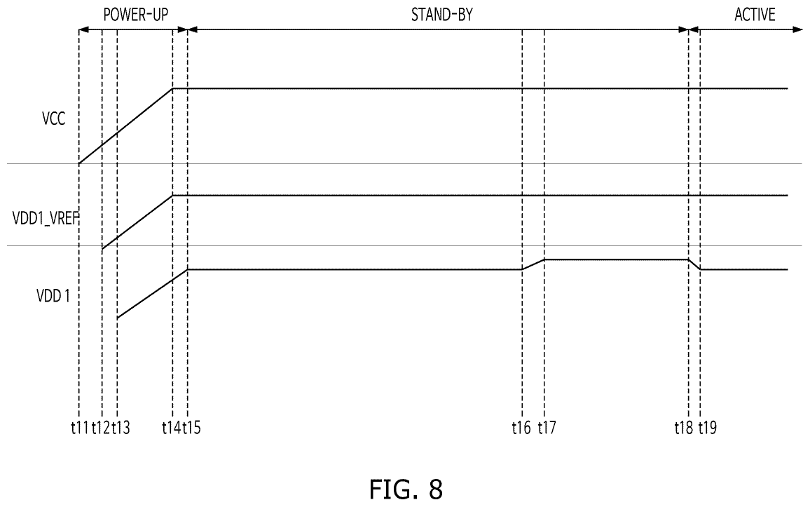

FIG. 8 is a diagram illustrating changes in the internal voltage VDD1 according to the voltage generating circuit 360 of FIG. 6.

Referring to FIGS. 6 and 8, the level of the external voltage VCC applied to the reference voltage generator 361 may increase from a time point t11 to a time point t14 during a power-up period POWER-UP. In response to the level of the external voltage VCC beginning to increase at t11, the level of the internal power reference voltage VDD1_VREF may start to increase at t12, and in response to the level of the internal power reference voltage VDD1_VREF beginning to increase at t12, the level of the internal voltage VDD1 supplied to the load circuit (e.g., 370 in FIG. 6) may start to increase at t13. In response to the level of the external voltage VCC, which has increased until t14 and is maintained from t14 and onward, the level of the internal voltage VDD1 may be maintained from a time point t15 and onward, allowing the load circuit to enter the standby mode. During the standby period STAND-BY in which the load circuit enters the standby mode, the level of each of the external voltage VCC, the internal power reference voltage VDD1_VREF, and the internal voltage VDD1 may be maintained.

Meanwhile, in the standby mode of the load circuit (e.g., 370 of FIG. 6), the standby driver 366 of FIG. 6 may be activated and supply the standby voltage to the load circuit as the internal voltage VDD1, and the active driver 367 may be deactivated.

In some cases, a leakage current may occur in the active driver 367 in the inactive state when the load circuit is in the standby mode. For example, the internal voltage VDD1 may start to increase from a time point t16 due to the leakage current occurred by the active driver 367 and may reach a specific level by a time point t17.

The increased level of the internal voltage VDD1 may be adjusted in response to the active driver 367 being activated in the active mode of the load circuit. For example, with the active period ACTIVE starting at a time point t18, the active driver 367 may be activated to supply the active voltage to the load circuit as the internal voltage VDD1. Accordingly, from t18, the level of the internal voltage VDD1 may start to fluctuate (e.g., drop) by the active driver 367, and from a time point t19, the active voltage may be supplied to the load circuit as the internal voltage VDD1. Accordingly, from a time point (e.g., t16) when the leakage current occurs to a time point (e.g., t19) when the active period begins and the active voltage starts to be supplied to the load circuit, the load circuit may be supplied with an abnormal level of voltage, and the reliability of the load circuit or memory device may be degraded.

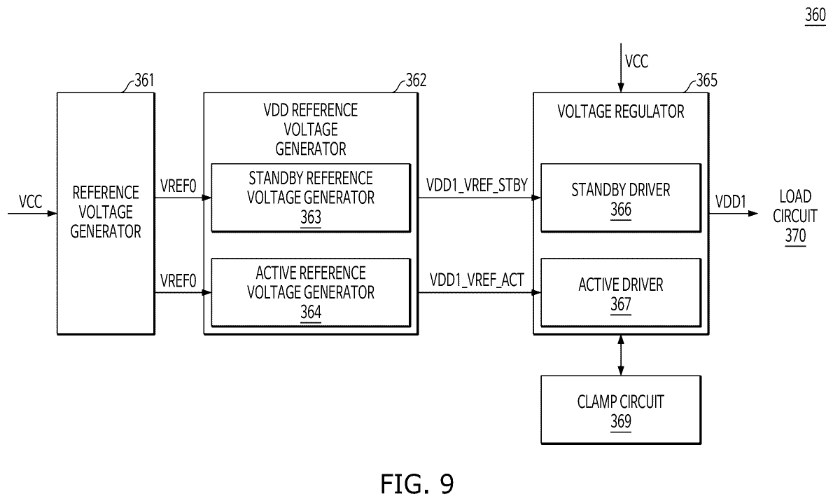

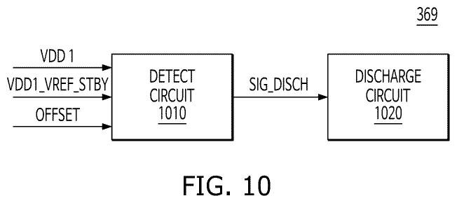

FIG. 9 is a diagram illustrating an example of the voltage generating circuit 360 including a clamp circuit 369, and FIG. 10 is a block diagram illustrating the clamp circuit 369 of FIG. 9 in more detail.

Referring to FIG. 9, the clamp circuit 369 may control the level of the internal voltage VDD1 supplied from the voltage regulator 365 to the load circuit 370. For example, in the standby mode of the load circuit 370, the voltage regulator 365 may generate the standby voltage based on the standby power reference voltage VDD1_VREF_STBY (or the internal power reference voltage VDD1_VREF in FIG. 5) and supply the standby voltage to the load circuit 370 as the internal voltage VDD1, and, in response to the standby voltage increasing to a level that exceeds a threshold level, the clamp circuit 369 may lower the standby voltage to a level equal to or lower than the threshold level. The standby voltage may have been increased to the level that exceeds the threshold level by the leakage current of the active driver 367 described above.

Referring to FIG. 10, the clamp circuit 369 may include a sense circuit 1010 (also referred to as a detect circuit) and a discharge circuit 1020.

The sense circuit 1010 may generate a discharge signal SIG_DISCH in response to the standby voltage exceeding the threshold level.

The threshold level may be determined based on the internal power reference voltage (e.g., VDD1_VREF of FIG. 5) associated with the load circuit 370. The threshold level may be determined based on the standby power reference voltage VDD1_VREF_STBY and an offset OFFSET. For example, the threshold level may be the sum of the standby power reference voltage VDD1_VREF_STBY and the offset OFFSET. The offset OFFSET may be a negative value, and the threshold level may be lower than the level of the standby power reference voltage VDD1_VREF_STBY (or the internal power reference voltage VDD1_VREF in FIG. 5). The threshold level and/or the offset OFFSET may be determined by the storage controller (e.g., 200 in FIG. 1).

The offset OFFSET may include a plurality of different offset values or may be one offset value selected from among a plurality of offset values. Accordingly, the threshold level may be variably adjusted according to various situations. For example, as strict control of the voltage level is required, the offset and the threshold level may be set to a lower level.

In response to receiving the discharge signal SIG_DISCH from the sense circuit 1010, the discharge circuit 1020 may lower the increased level of the standby voltage, which exceeds the threshold level, to a level equal to or lower than the threshold level.

In response to the discharge circuit 1020 lowering the standby voltage to the threshold level or below, the sense circuit 1010 may stop generating the discharge signal SIG_DISCH.

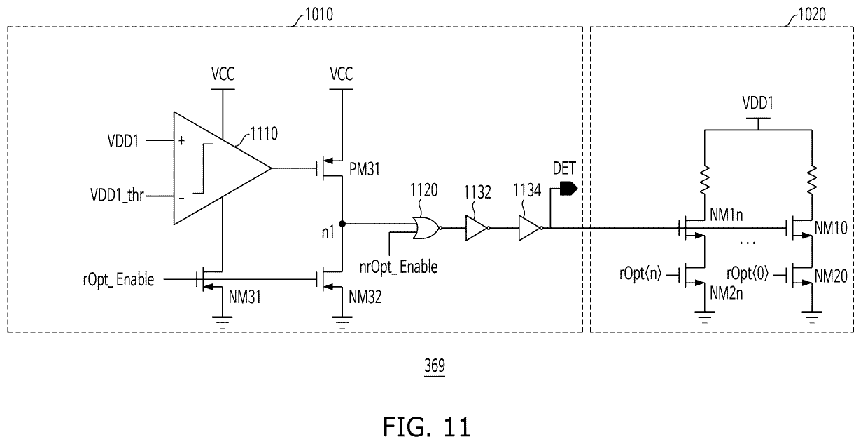

The operations of the sense circuit 1010 and the discharge circuit 1020 will be described in detail below with reference to FIG. 11.

FIG. 11 is a circuit diagram illustrating the clamp circuit 369 of FIG. 9 in detail. The clamp circuit 369 is not limited to the circuit diagram illustrated in FIG. 11, and the clamp circuit 369 may further include certain components or may not include some of the components illustrated in FIG. 11.

The sense circuit 1010 of the clamp circuit 369 may include a comparator 1110, a PMOS transistor PM31, NMOS transistors NM31 and NM32, one or more logic gates 1120, 1132, and 1134, and an output terminal DET. The comparator 1110 may be a signal amplifier. The one or more logic gates 1120, 1132, and 1134 may be connected to drain nodes of the PMOS transistor.

Referring to FIGS. 9 and 11, in response to the load circuit 370 being in the standby mode, an activation signal rOpt_Enable may be applied to the clamp circuit 369. The storage controller (e.g., 200 in FIG. 1) may determine the mode of the load circuit 370 as the standby mode or the active mode, and, in response to determining that the mode of the load circuit is the standby mode, may control the memory device (e.g., 300 in FIG. 1) to apply the activation signal rOpt_Enable to the clamp circuit 369. For example, the clamp circuit 369 may be activated only when the load circuit 370 is in the standby mode.

The activation signal rOpt_Enable may be applied to the gate electrodes of the NMOS transistors NM31 and NM32. For example, the activation signal rOpt_Enable may be a high level signal, and in response to the activation signal rOpt_Enable being applied to the gate electrode of the NMOS transistors NM31 and NM32, the clamp circuit 369 may be switched to a state in which the level of the internal voltage VDD1 can vary.

A low level signal nrOpt_Enable, which is the opposite level of the activation signal, may be applied to a NOR gate 1120. Accordingly, while the activation signal rOpt_Enable is applied to the gate electrode of the NMOS transistors NM31 and NM32, the output level of the NOR gate 1120 may vary according to the level of voltage applied to a node n1.

In response to determining the mode of the load circuit as the active mode, the storage controller may control the memory device (e.g., 300 in FIG. 1) to apply the deactivation signal to the clamp circuit 369. For example, the activation signal rOpt_Enable and the deactivation signal may be signals representing different logic values. The deactivation signal may be applied to the gate electrodes of the NMOS transistors NM31 and NM32. In response to the deactivation signal being applied to the gate electrode of the NMOS transistors NM31 and NM32, the clamp circuit 369 may be in a state in which the level of the internal voltage VDD1 cannot vary.

The comparator 1110 may compare the internal voltage VDD1 (e.g., the standby voltage) with a threshold voltage VDD1_thr. In response to the internal voltage VDD1 exceeding the threshold voltage VDD1_thr, the comparator 1110 may output a high level (e.g., the external voltage VCC) to the gate electrode of the PMOS transistor PM31, and in response to the level of the internal voltage VDD1 being equal to or lower than the threshold voltage VDD1_thr, the comparator 1110 may output a low level (e.g., a ground voltage) to the gate electrode of the PMOS transistor PM31. The threshold voltage VDD1_thr may be a voltage having a threshold level determined according to the aspect described above with reference to FIG. 10.

In response to the PMOS transistor PM31 being turned on with the low level output to the gate electrode of the PMOS transistor PM31, a high level (e.g., a logic value “1”) may be applied to the node n1 and the NOR gate 1120, and the discharge signal (e.g., SIG_DISCH of FIG. 10) may not be generated.

Alternatively, in response to the PMOS transistor PM31 being turned off with the high level output to the gate electrode of the PMOS transistor PM31, a low level (e.g., a logic value “0”) may be applied to the node n1 and the NOR gate 1120, and the one or more logic gates 1120, 1132, and 1134 may generate and output the discharge signal (e.g., SIG_DISCH of FIG. 10) and transmit the discharge signal to the discharge circuit 1020. The discharge signal may be applied to gate electrodes of a plurality of first NMOS transistors NM10 to NM1n (where, n is a natural number greater than or equal to 2) of the discharge circuit 1020.

The output terminal DET may transmit the sensed result of the sense circuit 1010 to an external device. For example, in response to determining that the level of the internal voltage VDD1 exceeds the level of the threshold voltage VDD1_thr, the output terminal DET may transmit a flag indicating the leakage generation of the voltage regulator (e.g., 365 in FIG. 9) to the storage controller.

The discharge circuit 1020 may include the plurality of first NMOS transistors NM10 to NM1n and a plurality of second NMOS transistors NM20 to NM2n. Any one of the plurality of first NMOS transistors NM10 to NM1n and any one of the plurality of second NMOS transistors NM20 to NM2n corresponding thereto may be connected to each other through one line. In another aspect, the discharge circuit 1020 may include one first NMOS transistor (e.g., NM10) and one second NMOS transistor (e.g., NM20).

The internal voltage VDD1 may be connected to source nodes of the plurality of first NMOS transistors NM10 to NM1n. The plurality of first NMOS transistors NM10 to NM1n may be turned on in response to the discharge signal generated by the sense circuit 1010 being applied to the gate electrodes of the plurality of first NMOS transistors NM10 to NM1n.

The source nodes of the plurality of second NMOS transistors NM20 to NM2n may be connected to drain nodes of the plurality of first NMOS transistors NM10 to NM1n. Drain nodes of the plurality of second NMOS transistors NM20 to NM2n may be connected to a ground node. At least some of the plurality of second NMOS transistors NM20 to NM2n may be turned on in the standby mode of the load circuit. For example, voltages rOpt<0> to rOpt<n> applied to gate electrodes of the plurality of second NMOS transistors NM20 to NM2n have different levels, and accordingly, at least some of the plurality of second NMOS transistors NM20 to NM2n may be turned on. The voltages rOpt<0> to rOpt<n> may be determined by the storage controller or the control logic circuit (e.g., 330 in FIG. 2). For example, the storage controller or the control logic circuit may set a higher voltage level to be discharged per unit time of the internal voltage VDD1, by setting the voltages rOpt<0> to rOpt<n> in such a way that the number of second NMOS transistors that are turned on increases among the plurality of second NMOS transistors NM20 to NM2n.

In response to the plurality of first NMOS transistors NM10 to NM1n being turned on, the internal voltage VDD1 (e.g., the standby voltage) may be discharged through a ground node connected to at least some of the plurality of second NMOS transistors NM20 to NM2n being turned on. Accordingly, if the internal voltage VDD1 abnormally rises, by discharging the internal voltage VDD1, the internal voltage VDD1 may be stably supplied to the load circuit, thereby enhancing the reliability of the load circuit or the memory device.

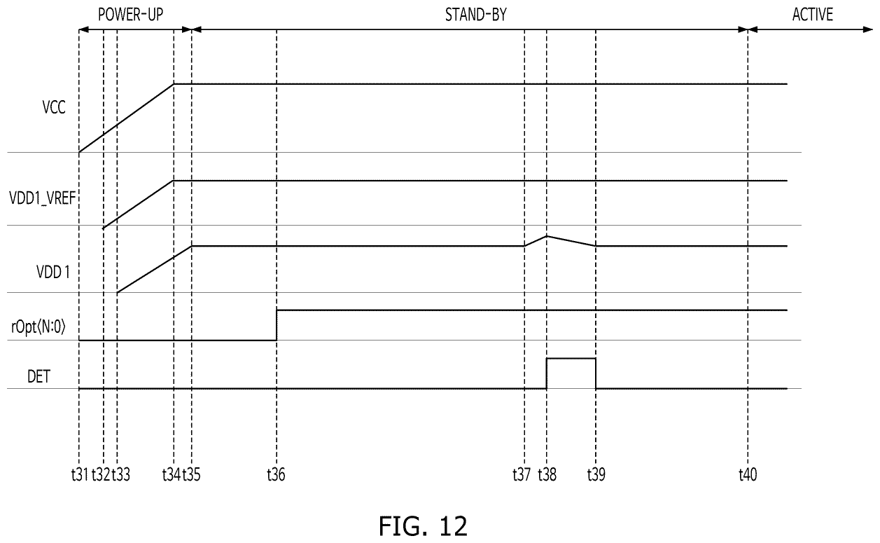

FIG. 12 is a view illustrating changes in the internal voltage VDD1 according to the clamp circuit 369 of FIG. 11.

Referring to FIGS. 9 and 12, from a time point t31 to a time point t34 in the power-up period POWER-UP, the level of the external voltage VCC applied to the reference voltage generator 361 may increase. In response to the level of the external voltage VCC beginning to increase at t31, the level of the internal power reference voltage VDD1_VREF may start to increase at t32, and in response to the level of the internal power reference voltage VDD1_VREF beginning to increase at t32, the level of the internal voltage VDD1 supplied to the load circuit (e.g., 370 in FIG. 9) may start to increase at t33. In response to the level of the external voltage VCC, which has increased until t34 and is maintained from t34 and onward, the level of the internal voltage VDD1 may be maintained from t35 and onward, allowing the load circuit to enter the standby mode. During the standby period STAND-BY in which the load circuit enters the standby mode, the level of each of the external voltage VCC, the internal power reference voltage VDD1_VREF, and the internal voltage VDD1 may be maintained.

Referring to FIGS. 11 and 12, starting from a time point t36, high-level voltages rOpt<0> to rOpt<n> may be applied to the gate electrodes of at least some of the plurality of second NMOS transistors NM20 to NM2n. FIG. 12 illustrates that the voltages rOpt<0> to rOpt<n> have the same level, but aspects are not limited thereto, and at least some of the voltages rOpt<0> to rOpt<n> may have a level sufficient to turn on the second NMOS transistor, while the other voltages rOpt<0> to rOpt<n> may have a level insufficient to turn on the second NMOS transistor. Unlike the illustration in FIG. 12, at least some of the voltages rOpt<0> to rOpt<n> may start to be applied at a high level from any time point during the standby period STAND-BY (e.g., from t35, which is the start time point of the standby period STAND-BY).

While the load circuit is in the standby mode, the leakage current may occur in the active driver 367 in the inactive state starting from a time point t37. For example, the internal voltage VDD1 may start to increase from the time point t37 due to the leakage current occurred by the active driver 367 and may reach a specific level by a time point t38.

Referring to FIGS. 11 and 12, by the time point t38, the level of the internal voltage VDD1 may have exceeded the level of the threshold voltage VDD1_thr. In response to the level of the internal voltage VDD1 exceeding the level of the threshold voltage VDD1_thr at t38, the comparator 1110 may output a high level (e.g., the external voltage VCC) to the gate electrode of the PMOS transistor PM31, and in response to the high level being output to the gate electrode of the PMOS transistor PM31 to turn off the PMOS transistor PM31, the one or more logic gates 1120, 1132, and 1134 may generate/output the discharge signal (e.g., SIG_DISCH of FIG. 10) to turn on the plurality of first NMOS transistors NM10 to NM1n. Starting from t38, in response to determining that the level of the internal voltage VDD1 exceeds the level of the threshold voltage VDD1_thr, the output terminal DET may transmit a flag indicating the leakage generation of the voltage regulator (e.g., 365 in FIG. 9) to the storage controller.

Starting from t38, in response to the plurality of first NMOS transistors NM10 to NM1n being turned on, the internal voltage VDD1 (e.g., the standby voltage) may be discharged.

Starting from a time point t39, in response to the internal voltage VDD1 being discharged at or below the level of the threshold voltage VDD1_thr, the comparator 1110 may output a low level (e.g., the ground voltage) to the gate electrode of the PMOS transistor PM31. Accordingly, the one or more logic gates 1120, 1132, and 1134 may stop generating the discharge signal, and from the time point t39, the discharge of the internal voltage VDD1 may be stopped.

At a time point t40, the load circuit may be switched to the active mode, and it may correspond to the active period ACTIVE from t40.

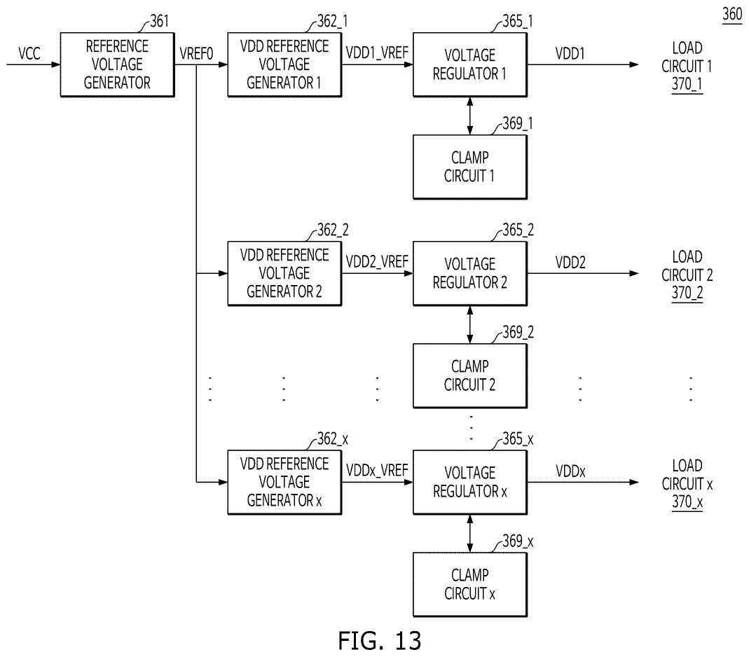

FIG. 13 is a block diagram of the voltage generating circuit 360.

The voltage generating circuit 360 may include a plurality of internal power reference voltage generators 362_1 to 362_x, voltage regulators 365_1 to 365_x, and clamp circuits 369_1 to 369_x for a plurality of load circuits 370_1 to 370_x (where, x is a natural greater than or equal to 2) in the memory device (e.g., 300 in FIG. 1).

Each of the plurality of internal power reference voltage generators 362_1 to 362_x, the plurality of voltage regulators 365_1 to 365_x, the plurality of clamp circuits 369_1 to 369_x, and the plurality of load circuits 370_1 to 370_x may correspond to the internal power reference voltage generator, the voltage regulator, the clamp circuit, and the load circuit according to various aspects described with reference to FIGS. 5 to 12. For example, the plurality of internal power reference voltage generators 362_1 to 362_x may generate internal power reference voltages VDD1_VREF to VDDx_VREF using the reference voltage VREF0, and the plurality of voltage regulators 365_1 to 365_x may generate internal voltages VDD1 to VDDx based on the internal power reference voltages VDD1_VREF to VDDx_VREF, and supply the generated internal voltages VDD1 to VDDx to the load circuits 370_1 to 370_x. The plurality of clamp circuits 369_1 to 369_x may control the levels of the internal voltages VDD1 to VDDx.

Alternatively, some of the plurality of clamp circuits 369_1 to 369_x may be omitted. For example, the levels of the internal voltages VDD1 to VDDx for some of the plurality of load circuits 370_1 to 370_x may not be controlled by the clamp circuit.

The present disclosure is not limited by the aspects described above and accompanying drawings, and various forms of substitution, transformation, and change will be possible by those of ordinary skill in the art within the scope not departing from the technical idea of the present disclosure, which will also fall within the scope of the present disclosure. For example, one or more steps in the process described with reference to the flowchart illustrated in some drawings may be omitted, the order of each step may be changed, one or more steps may be performed overlapping each other in time, or one or more steps may be repeatedly performed multiple times.

What is claimed is:

1. A memory device, comprising:
a load circuit;
one or more reference voltage generators configured to generate an internal power reference voltage;
a voltage regulator configured to generate an internal voltage based on the internal power reference voltage and supply the generated internal voltage to the load circuit; and
a clamp circuit configured to control a level of the internal voltage, wherein the voltage regulator is further configured to generate a standby voltage based on the internal power reference voltage in a standby mode of the load circuit and supply the generated standby voltage to the load circuit as the internal voltage, and
the clamp circuit is further configured to, in response to the standby voltage increasing to a first level exceeding a threshold level in the standby mode of the load circuit, lower the standby voltage to a second level equal to or lower than the threshold level.

2. The memory device according to claim 1, wherein the one or more reference voltage generators comprises:
a first reference voltage generator configured to generate a reference voltage using an external voltage; and
a second reference voltage generator configured to generate the internal power reference voltage using the reference voltage.

3. The memory device according to claim 2, wherein
the second reference voltage generator comprises:
a first internal power reference voltage generator configured to generate a standby reference voltage using the reference voltage in the standby mode of the load circuit; and
a second internal power reference voltage generator configured to generate an active reference voltage using the reference voltage in an active mode of the load circuit, and
the internal power reference voltage comprises the standby reference voltage and the active reference voltage.

4. The memory device according to claim 3, wherein the voltage regulator comprises:
a standby driver configured to generate the standby voltage based on the standby reference voltage and supply the generated standby voltage to the load circuit as the internal voltage in the standby mode of the load circuit; and
an active driver configured to generate an active voltage based on the active reference voltage and supply the generated active voltage to the load circuit as the internal voltage in the active mode of the load circuit.

5. The memory device according to claim 4, wherein, in the standby mode of the load circuit, in response to the standby voltage increasing to the first level by a leakage current of the active driver, the clamp circuit is configured to lower the standby voltage increased by the leakage current to the second level.

6. The memory device according to claim 4, wherein
the active driver comprises a plurality of unit drivers connected in parallel,
each of the plurality of unit drivers comprises an amplifier and a pass transistor, and
the active voltage is generated using the amplifiers and the pass transistors of the plurality of unit drivers.

7. The memory device according to claim 4, wherein the active driver is a low dropout (LDO) circuit.

8. The memory device according to claim 1, wherein the load circuit comprises at least one of a memory cell array, an address decoder, a control logic circuit, a page buffer circuit, or an input/output circuit.

9. The memory device according to claim 1, wherein
the clamp circuit comprises:
a sense circuit configured to generate a discharge signal in response to the standby voltage exceeding the threshold level; and
a discharge circuit configured to lower the standby voltage increased to the first level to the second level in response to receiving the discharge signal from the sense circuit.

10. The memory device according to claim 9, wherein the sense circuit is further configured to stop the generation of the discharge signal in response to the discharge circuit lowering the standby voltage to the second level.

11. The memory device according to claim 9, wherein
the sense circuit comprises:
a PMOS transistor;
a comparator configured to compare the standby voltage and the threshold level, output a high level to a gate electrode of the PMOS transistor in response to the standby voltage exceeding the threshold level, and output a low level to the gate electrode of the PMOS transistor in response to the standby voltage being equal to or lower than the threshold level; and
one or more logic gates connected to a drain node of the PMOS transistor and configured to generate the discharge signal and transmit the generated discharged signal to the discharge circuit in response to the PMOS transistor being turned off with the high level applied to the gate electrode of the PMOS transistor.

12. The memory device according to claim 9, wherein
the discharge circuit comprises:
a plurality of first NMOS transistors with source nodes of the plurality of first NMOS transistors connected to the internal voltage and configured to be turned on in response to the discharge signal being applied to gate electrodes of the plurality of first NMOS transistors; and
a plurality of second NMOS transistors with source nodes of the plurality of second NMOS transistors connected to drain nodes of the plurality of first NMOS transistors and with drain nodes of the plurality of second NMOS transistors connected to a ground node, wherein at least some of the plurality of second NMOS transistors are turned on in the standby mode of the load circuit, and
in response to the plurality of first NMOS transistors being turned on, the standby voltage is discharged through the ground node connected to the at least some of the second NMOS transistors that are turned on in the standby mode of the load circuit.

13. A memory device, comprising:
a load circuit;
one or more reference voltage generators configured to generate an internal power reference voltage;
a voltage regulator configured to generate an internal voltage based on the internal power reference voltage and supply the generated internal voltage to the load circuit; and
a clamp circuit configured to control a level of the internal voltage, wherein the voltage regulator is further configured to generate a standby voltage based on the internal power reference voltage and supply the generated standby voltage to the load circuit as the internal voltage in a standby mode of the load circuit, and
the clamp circuit is further configured to, in response to the standby voltage increasing to a first level exceeding a threshold level in the standby mode of the load circuit, lower the standby voltage to a second level equal to or lower than the threshold level,
the clamp circuit comprises:
a PMOS transistor;
a comparator configured to compare the standby voltage and the threshold level, output a high level to a gate electrode of the PMOS transistor in response to the standby voltage exceeding the threshold level, and output a low level to the gate electrode of the PMOS transistor in response to the standby voltage being equal to or lower than the threshold level;
one or more logic gates connected to a drain node of the PMOS transistor and generating a discharge signal in response to the PMOS transistor being turned off with the high level applied to the gate electrode of the PMOS transistor;
a plurality of first NMOS transistors with source nodes of the plurality of first NMOS transistors connected to the internal voltage and configured to be turned on in response to the discharge signal being applied to gate electrodes of the plurality of first NMOS transistors; and
a plurality of second NMOS transistors with source nodes of the plurality of second NMOS transistors connected to drain nodes of the plurality of first NMOS transistors and with drain nodes of the plurality of second NMOS transistors connected to a ground node, wherein at least some of the plurality of second NMOS transistors are turned on in the standby mode of the load circuit, and
in response to the plurality of first NMOS transistors being turned on, the standby voltage is discharged through the ground node connected to the at least some of the second NMOS transistors that are turned on in the standby mode of the load circuit.

14. A storage device, comprising:
a memory device comprising a load circuit, one or more reference voltage generators configured to generate an internal power reference voltage, a voltage regulator configured to generate an internal voltage based on the internal power reference voltage and supply the generated internal voltage to the load circuit, and a clamp circuit configured to control a level of the internal voltage; and
a storage controller connected to the memory device, wherein the voltage regulator is further configured to generate a standby voltage based on the internal power reference voltage in a standby mode of the load circuit and supply the generated standby voltage to the load circuit as the internal voltage, and
the clamp circuit is further configured to, in response to the standby voltage increasing to a first level exceeding a threshold level in the standby mode of the load circuit, lower the standby voltage to a second level equal to or lower than the threshold level.

15. The storage device according to claim 14, wherein the storage controller is configured to determine the threshold level based on the internal power reference voltage.

16. The storage device according to claim 15, wherein
the storage controller is further configured to determine the threshold level based on a level obtained by summing the internal power reference voltage and a predetermined offset, and
the threshold level is lower than the internal power reference voltage.

17. The storage device according to claim 14, wherein the storage controller is further configured to:
determine a mode of the load circuit as the standby mode or active mode; and
in response to determining the mode of the load circuit as the standby mode, control the memory device so that the voltage regulator generates the standby voltage.

18. The storage device according to claim 17, wherein the storage controller is further configured to, in response to determining the mode of the load circuit as the standby mode, control the memory device so that an activation signal is applied to the clamp circuit, thereby switching the clamp circuit to a state in which the level of the internal voltage is variable.

19. The storage device according to claim 17, wherein the storage controller is further configured to, in response to determining the mode of the load circuit as the active mode, control the memory device so that a deactivation signal is applied to the clamp circuit, thereby switching the clamp circuit to a state in which the level of the internal voltage is non-variable.

20. The storage device according to claim 14, wherein the clamp circuit is further configured to, in response to determining that the standby voltage exceeds the threshold level, transmit a flag indicating a leakage generation of the voltage regulator to the storage controller.
